(19) United States
(12) Patent Application Publication
(10) Pub. No.: US 2002/0185944 A1
(43) Pub. Date: Dec. 12, 2002

(54) Detachment and assembly structure of master computer's faceplate

(76) Inventor: Feng-Ming Chen, Yung Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/028,678

(22) Filed: Dec. 28, 2001

(30) Foreign Application Priority Data
Jun. 7, 2001 (TW) 90209442

(51) Int. Cl. H05K 7/18

(52) U.S. Cl. 312/223.2; 312/265.5; 312/265.6

(57) ABSTRACT

A detachment and assembly structure of a master computer's faceplate comprises a frame body, a faceplate, and a control rod. One side of the faceplate uses retaining bodies to retain retaining holes of the frame body. The control rod is pivotally disposed at the other side of the frame body. A rejection portion, a receiving groove, and a wrench portion are disposed on the control rod. The other side of the faceplate uses projective poles to match the receiving groove so that the faceplate can be assembled at the front end of the frame body. The wrench portion is used to turn the control rod to let the projective poles come off the receiving groove and the rejection portion shore up the projective poles so that the projective poles can come off the frame body. The retaining bodies can thus be separated from the retaining holes, thereby accomplishing detachment operation.

### FIELD OF THE INVENTION

The present invention relates to a detachment and assembly structure of a master computer's faceplate and, more particularly, to a detachment and assembly structure of a master computer's faceplate of convenient detachment and assembly without the need of using screws.

### BACKGROUND OF THE INVENTION

After a user has purchased a computer, maintenance, replacement, or expansion is usually made afterwards. The most important devices of a computer (e.g., the central processing unit (CPU), the memories, the chipsets, and the interface cards) are all installed on a motherboard, which is disposed in a master computer. However, because a faceplate is generally locked with screws at the front end of the master computer, the detachment and assembly are very inconvenient, resulting in inconvenience in maintenance, replacement, and expansion afterwards.

Accordingly, the above master computer's faceplate has drawbacks and inconvenience in practical use. The present invention aims to resolve the problems in the prior art.

### SUMMARY OF THE INVENTION

The primary object of the present invention is to provide a detachment and assembly structure of a master computer's faceplate. The assembly and detachment operation of the faceplate with a frame body can be quickly accomplished. It is not necessary to use screws to fixedly lock the faceplate at the front end of the master computer. The detachment and assembly is thus very convenient, hence facilitating maintenance, replacement, and expansion afterwards.

To achieve the above object, the present invention provides a detachment and assembly structure of a master computer's faceplate, which comprises a frame body, a faceplate, and one or a plurality of control rods. A plurality of retaining holes are disposed at one side of the front end of the frame body. A plurality of retaining bodies are disposed at one side of the faceplate. The retaining bodies can be retained with the retaining holes. A plurality of projective poles are disposed at the other side of the faceplate. The control rod is pivotally disposed at the other side of the frame body. A rejection portion, a receiving groove, and a wrench portion are disposed on the control rod. The projective poles can be matched with the receiving groove of the control rod so that the faceplate can be assembled at the front end of the frame body. Thereby, when the wrench portion is used to turn the control rod, the projective poles of the faceplate can come off the receiving groove of the control rod, and the rejection portion of the control rod can shore up the projective poles to let the projective poles come off the frame body. The faceplate can thus be detached from the front end of the frame body.

The various objects and advantages of the present invention will be more readily understood from the following detailed description when read in conjunction with the appended drawing, in which:

### BRIEF DESCRIPTION OF THE DRAWINGS:

FIG. 1 is an exploded perspective view of the present invention;

FIG. 2 is a perspective assembly view of the present invention;

FIG. 3 is a perspective view of the control rod of the present invention;

FIG. 4 is a cross-sectional view showing the connection of the control rod with a master computer of the present invention;

FIG. 5 is an action diagram of the present invention;

FIG. 6 is another action diagram of the present invention;

FIG. 7 is yet another action diagram of the present invention; and

FIG. 8 is still yet another action diagram of the present invention.

### DETAILED DESCRIPTION OF THE PREFERRED EMBODIMENTS

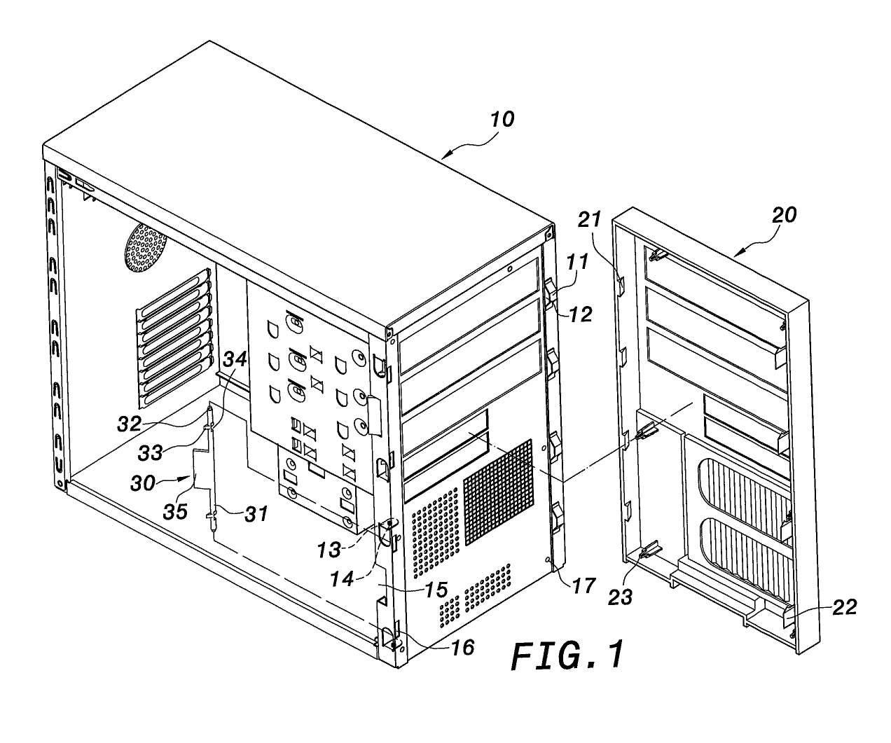

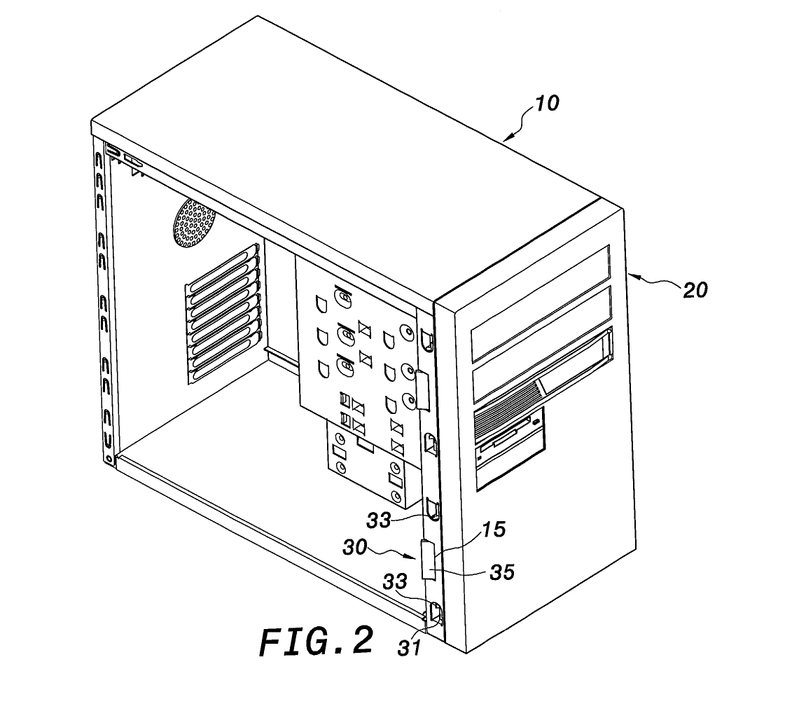

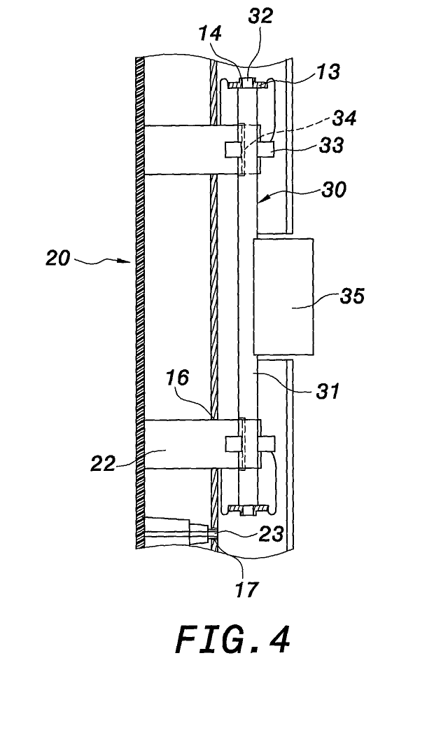

Referring to FIGS. 1 to 4, the present invention provides a detachment and assembly structure of a computer master's faceplate. A frame body 10 of the master computer is roughly a cuboid. A faceplate 20 is disposed at the front end of the frame body 10. The faceplate 20 and the frame body 10 can be separable. The present invention is mainly characterized in that a plurality of retaining elements 11 are disposed at one side of the front end of the frame body 10. A retaining hole 12 is formed inside each of the retaining elements 11. A plurality of retaining bodies 21 are disposed at one side of the rear end of the faceplate 20. The retaining bodies 21 can be retained with the retaining holes 12 so that one side of the faceplate 20 can be joined with the frame body 10 in retaining way.

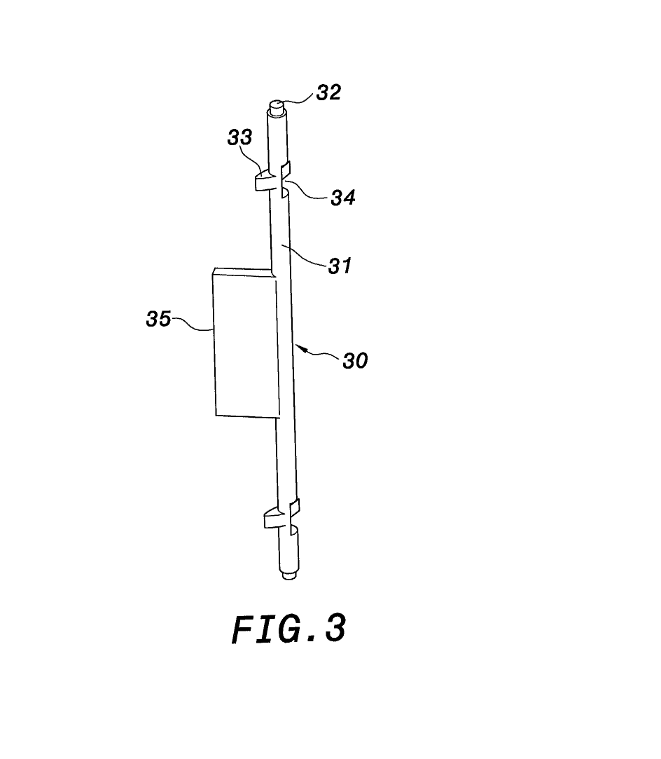

One or a plurality of control rods 30 (shown in FIG. 3) are pivotally disposed at the other side of the frame body 10 of the master computer. The control rod 30 has a circular rod body 31. Two ends of the rod body 30 form pivotal shafts 32. One or a plurality of rejection portions 33 and receiving grooves 34 are disposed on the rod body 31. A wrench portion 35 is also disposed on the rod body 31. A plurality of ear sheets 13 corresponding to the pivotal shafts 32 are disposed at the other side of the front end of the frame body 10. A pivotal hole 14 is disposed on each of the ear sheets 13. The control rod 30 uses the two pivotal shafts 32 to pivotally match the two pivotal holes 14 so that the control rod 30 can be pivotally disposed at the frame body 10 of the master computer. A first through hole 15 is disposed on the frame body 10 to be protruded out by the wrench portion 35 of the control rod 30 so that the wrench portion 35 can be used to turn the control rod 30.

A plurality of projective poles 22 corresponding to the receiving grooves 34 are disposed at the other side of the rear end of the faceplate 20. A second through hole 16 is disposed on the frame body 10 so that the projective poles 22 can penetrate into the frame body 10. Corresponding positioning holes 17 and positioning poles 23 can be disposed on the front end of the frame body 10 and the faceplate 20, respectively. The positioning holes 17 and the positioning poles 17 can match mutually to provide positioning function for the frame body 10 and the faceplate 20.

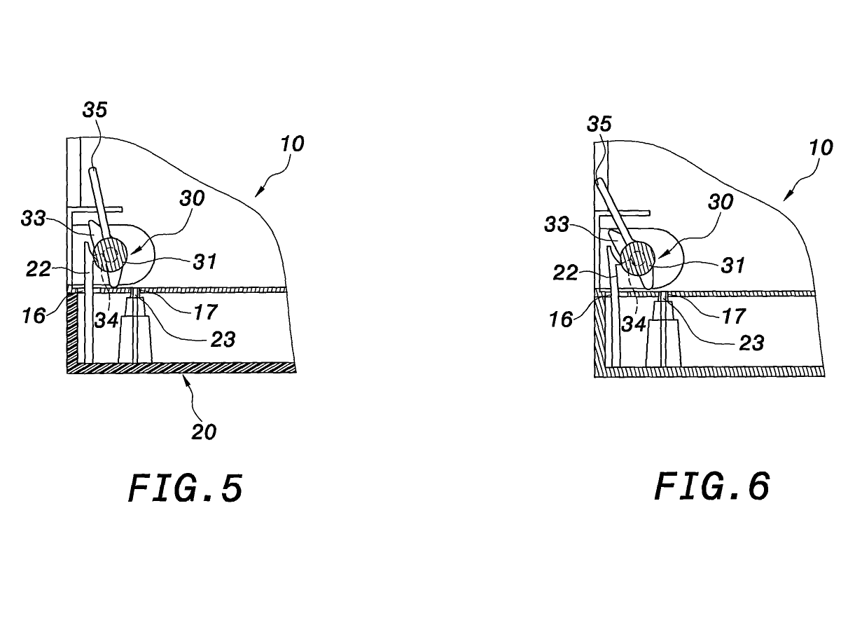

When the faceplate 20 is to be assembled with the frame body 10, it is necessary to first retain the retaining bodies 21 at one side of the faceplate 20 with the retaining holes 12 at one side of the frame body 10 so as to let one side of the faceplate 20 be joined with the frame body 10. Next, the projective poles 22 at the other side of the faceplate 20 penetrate into the frame body 10 via the second through hole 16 and are matched with the receiving grooves 34 of the control rod 30 so that the other side of the faceplate 20 can also be joined with the frame body 10, as shown in FIG. 5. The faceplate 20 can thus be assembled at the front end of the frame body 10. Thereby, the assembly operation of the master computer faceplate 20 is accomplished.

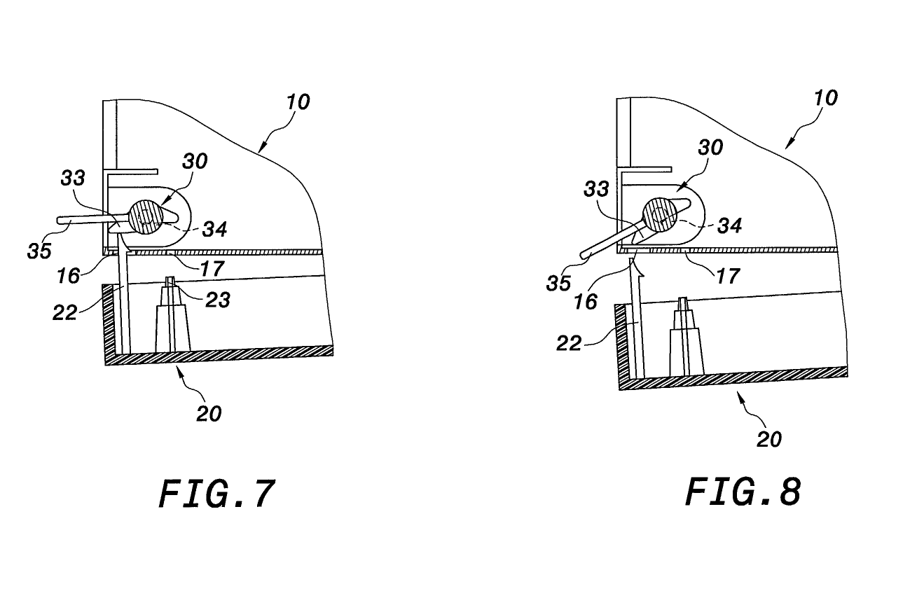

When the faceplate 20 is to be detached from the frame body 10, the wrench portion 35 can be used to turn the control rod 30 to let the projective poles 22 of the faceplate 20 come off the receiving grooves 34 of the control rod 30, as shown in FIG. 6. Next, the rejection portion 33 of the control rod 30 will shore up the projective poles 22 (as shown in FIG. 7) to let the projective poles 22 come off the second through hole 16 of the frame body 10 (as shown in FIG. 8). The retaining bodies 21 of the faceplate 20 can thus be separated from the retaining holes 12 of the frame body 10 to accomplish the detachment operation of the master computer's faceplate 20.

To sum up, the assembly operation of the faceplate 20 and the frame body 10 of the present invention can be quickly accomplished. Moreover, when the faceplate 20 is to be detached from the frame body 10, it is only necessary to turn the control rod 30 to let the projective poles 22 of the faceplate 20 come off the receiving grooves 34 of the control rod 30 and the rejection portion 33 of the control rod 30 shore up the projective poles 22 so that the projective poles 22 can come off the frame body 10. Subsequently, the retaining bodies 21 of the faceplate 20 can be separated from the retaining holes 12 of the frame body 10, hence quickly accomplishing the detachment operation of the master computer's faceplate 20. The faceplate of the present invention can be joined at the front side of the frame body without the need of using screws. The detachment and assembly are very convenient, hence facilitating maintenance, replacement, and expansion afterwards.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A detachment and assembly structure of a master computer's faceplate, comprising:
a frame body with a plurality of retaining holes disposed at one side of a front end thereof;
a faceplate with a plurality of retaining bodies disposed at one side thereof, said retaining bodies being retained with said retaining holes, a plurality of projective poles being disposed at the other side of said faceplate; and
one or more control rods pivotally disposed at the other side of said frame body, a rejection portion, a receiving groove, and a wrench portion being disposed on said control rod, said projective poles at the other side of said faceplate being matched with said receiving groove of said control rod so that said faceplate can be assembled at the front end of said frame body;
whereby said wrench portion can be used to turn said control rod to let said projective poles of said faceplate come off said receiving groove of said control rod and said rejection portion of said control rod shore up said projective poles so that said projective poles can come off said frame body, thereby letting said faceplate be separated from the front end of said frame body.

2. The detachment and assembly structure of a master computer's faceplate as claimed in claim 1, wherein a plurality of retaining elements are disposed at one side of the front end of said frame body, and said retaining holes are formed inside said retaining elements.

3. The detachment and assembly structure of a master computer's faceplate as claimed in claim 1, wherein a through hole is disposed on said frame body so that said projective poles can pass therethrough to penetrate into said frame body.

4. The detachment and assembly structure of a master computer's faceplate as claimed in claim 1, wherein corresponding positioning holes and positioning poles can be respectively disposed on the front end of said frame body and said faceplate, and said positioning holes and said positioning poles can match mutually.

5. The detachment and assembly structure of a master computer's faceplate as claimed in claim 1, wherein said control rod has a rod body, two ends of said rod body forming pivotal shafts, said rejection portion, said receiving groove, and said wrench portion being disposed on said rod body, ear sheets corresponding to said pivotal shafts being disposed at the other side of the front end of said frame body, a pivotal hole being disposed on each of said ear sheets, said control rod using said pivotal shafts to pivotally match said pivotal holes so that said control rod can be pivotally disposed on said frame body.
